(19) United States
(12) Patent Application Publication
(10) Pub. No.: US 2026/0006804 A1
(43) Pub. Date: Jan. 1, 2026

(54) SEMICONDUCTOR STRUCTURE WITH CAPACITOR AND METHOD FOR MANUFACTURING THE SAME

(71) Applicant: TAIWAN SEMICONDUCTOR MANUFACTURING COMPANY LTD., HSINCHU (TW)

(72) Inventors: TING-CHEN HSU, TAICHUNG CITY (TW); MING-HSUN LIN, HSINCHU (TW); JYUN-YING LIN, YILAN COUNTY (TW); HSIN-LI CHENG, HSINCHU COUNTY (TW)

(21) Appl. No.: 18/754,212

(22) Filed: Jun. 26, 2024

(51) Int. Cl. H10D 1/00; H10D 1/68

(52) U.S. Cl. CPC H10D 1/042; H10D 1/716

(57) ABSTRACT

A semiconductor structure is provided. The semiconductor structure includes a semiconductor substrate, at least one capacitor structure and a plurality of conductive vias. The semiconductor substrate has a plurality of substrate regions formed in a front side of the semiconductor substrate. The capacitor structure is formed over the front side of the semiconductor substrate and along sidewalls of the substrate regions. The capacitor structure includes a plurality of electrodes and a plurality of capacitor dielectric layers alternately disposed on the semiconductor substrate; and a plurality of connecting structures. Each connecting structure is electrically coupled to one of the plurality of electrodes. Tops of the connecting structures are coplanar with each other and substantially parallel to the front side of the semiconductor substrate. Each of the conductive vias is coupled to one of the electrodes.

### BACKGROUND

A trench capacitor exhibits high power density relative to some other capacitor types within a semiconductor integrated circuit (IC). As such, trench capacitors are utilized in applications such as dynamic random-access memory (DRAM) storage cells, among other applications. Some examples of trench capacitors include high density deep trench capacitors (DTCs) which are utilized in advanced technology node processes.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a cross-sectional view of a semiconductor structure in accordance with some another embodiments of the present disclosure.

FIG. 2 is a fragmentary perspective view of a semiconductor structure in accordance with some embodiments of the present disclosure.

FIG. 3 is a fragmentary cross-sectional view of a semiconductor structure in accordance with some embodiments of the present disclosure.

FIG. 4 is a fragmentary cross-sectional view of a semiconductor structure in accordance with some alternative embodiments of the present disclosure.

FIG. 5 is a fragmentary cross-sectional view of a semiconductor structure in accordance with some alternative embodiments of the present disclosure.

FIG. 6 is a cross-sectional view of a semiconductor structure in accordance with some embodiments of the present disclosure.

FIG. 7 is a top view of a semiconductor structure in accordance with some embodiments of the present disclosure.

FIG. 8 is a flowchart illustrating a method of fabricating a semiconductor structure in accordance with some another embodiments of the present disclosure.

FIGS. 9A to 9H illustrate diagrammatic cross-sectional side views of some another embodiment of a semiconductor structure at various stages of fabrication, according to the method of FIG. 8.

FIGS. 10A to 10H illustrate diagrammatic cross-sectional side views of some another embodiment of a semiconductor structure at various stages of fabrication, according to the method of FIG. 8.

### DETAILED DESCRIPTION OF THE DISCLOSURE

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Also, the components disclosed herein may be arranged, combined, or configured in ways different from the exemplary embodiments shown herein without departing from the scope of the present disclosure. It is understood that those skilled in the art will be able to devise various equivalents that, although not explicitly described herein, embody the principles of the present invention.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

A basic trench capacitor is a small three-dimensional device formed by etching a trench into a semiconductor substrate. A DTC is used to provide capacitance to various ICs. Deep trench capacitors can be used in a variety of semiconductor chips for high areal capacitance. Typically, a deep trench capacitor comprises a metal-insulator-metal (MIM) stack including a plurality of capacitor structures formed on a front surface of the substrate and along sidewalls of substrate regions and a plurality of conductive vias. Each capacitor structure comprises a plurality of electrodes and a plurality of dielectric layers alternately disposed between the electrodes. Therefore, the plurality of electrodes are formed on the front side surface of the substrate and along the sidewalls of the substrate regions, so that a distance between one of the plurality of electrodes and the substrate is different from that between another one of the plurality of electrodes and the substrate. For example, a lowest electrode has a smallest distance from the substrate while an uppermost electrode has a greatest distance from the substrate. Each of the plurality of conductive via is electrically coupled to a corresponding one of the plurality of the electrodes on the substrate. Since the distances between the plurality of electrodes and the substrate are different, the conductive vias have different landing paths for the conductive vias to be electrically coupled to the corresponding one of the plurality of the electrodes.

Before connecting the conductive vias to the electrodes, there is a need to form a recess in each of the plurality of the electrodes so as to expose upper surfaces of the electrodes. Then, the conductive vias can land on the upper surfaces of the corresponding electrodes. However, it is difficult to accurately form recesses with a consistent depth in the plurality of the electrodes because etching conditions for forming recesses in the electrodes at different levels are difficult to control. That is, a depth of one recess may be different from a depth of another recess, so the DTC would have small process window due to different landing paths of the conductive vias on the electrodes. Furthermore, it is also likely that a bottom of the recess may be located on a dielectric layer, which means that a conductive via may connect to the dielectric layer rather than an electrode as designed. On the other hand, when the number of electrodes is increased, forming recesses would be more challenged as the landing paths become longer.

Therefore, the present disclosure provides a DTC structure including conductive vias with consistent landing paths, which improves process window and reduces contact resistance (Rc), and leakage and open risks. Such DTC structure has a wider process window so that the conductive vias can be accurately coupled to electrodes of the DTC structure.

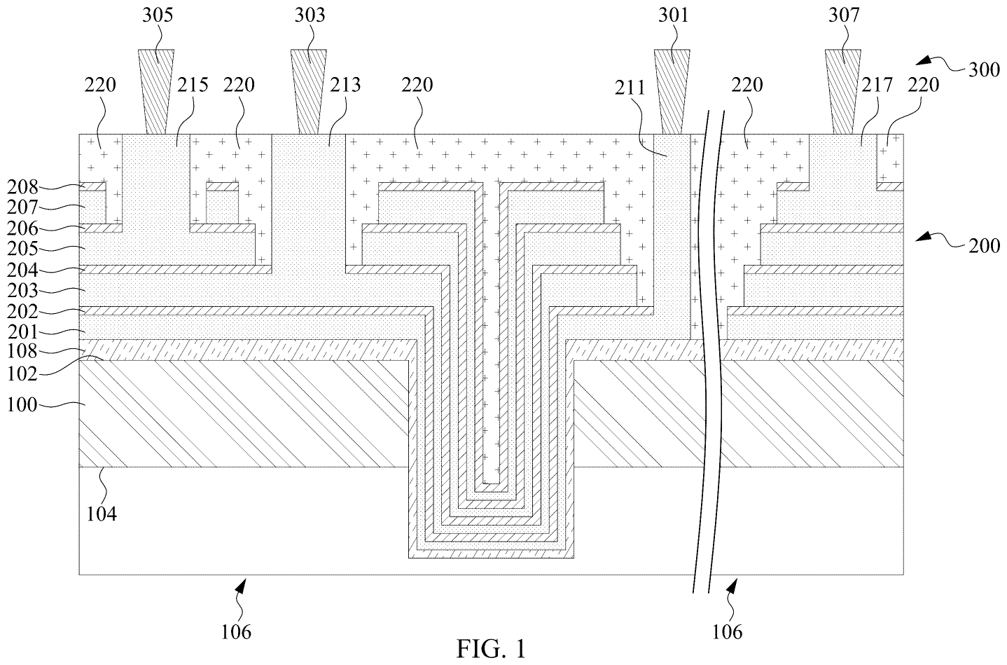

FIG. 1 illustrates a cross-sectional view of some embodiments of a semiconductor structure having a semiconductor substrate 100, at least one capacitor structure 200 and a plurality of conductive vias 300.

The semiconductor substrate 100 comprises a front side 102, a back side 104 and a plurality of substrate regions 106. The semiconductor substrate 100 may be, for example, a bulk semiconductor substrate, such as a bulk substrate of monocrystalline silicon or some other silicon, or a silicon-on-insulator (SOI) substrate. The semiconductor substrate 100 is overlaid with a liner layer 108. The liner layer 108 extends along the front side 102 of the semiconductor substrate 100 and along the sidewalls of the substrate regions 106. The liner layer 108 may, for example, be or comprise an oxide (e.g., such as silicon dioxide) or another dielectric material.

The capacitor structure 200 overlies onto the liner layer 108, so the liner layer 108 is sandwiched between the semiconductor substrate 100 and the capacitor structure 200. The capacitor structure 200 comprises a plurality of electrodes 201, 203, 205 and 207, a plurality of capacitor dielectric layers 202, 204, 206 and 208 alternately disposed on the electrodes 201, 203, 205 and 207, a plurality of connecting structures 211, 213, 215 and 217, and a plurality of separation structures 220.

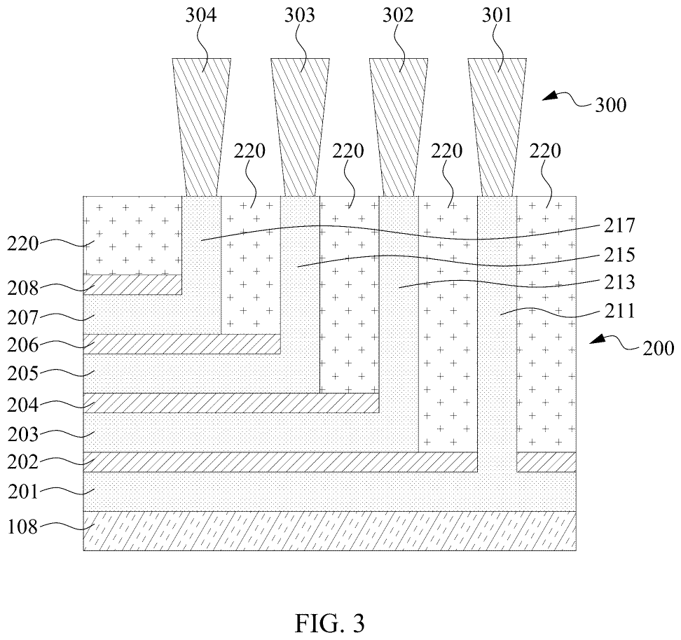

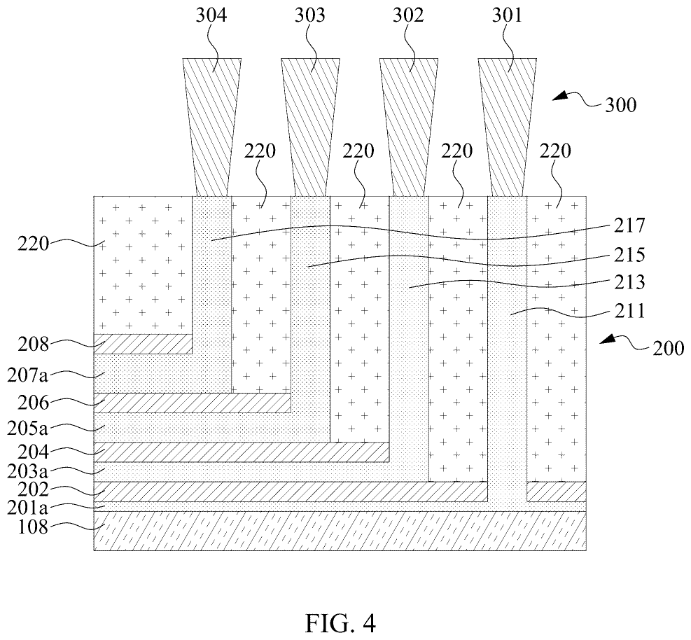

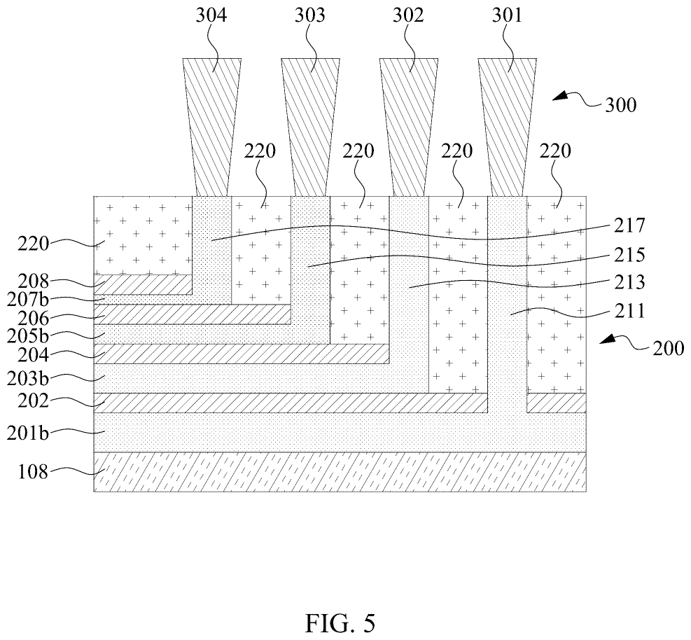

The plurality of electrodes 201, 203, 205 and 207 include a first electrode 201, a second electrode 203, a third electrode 205, and a fourth electrode 207. Each of the plurality of electrodes comprises a first conductive material (e.g., titanium, titanium nitride, tantalum, tantalum nitride, tungsten, aluminum, copper and so on). Thicknesses of the plurality of electrodes 201, 203, 205 and 207 can be designed as demand. For example, the thicknesses of the plurality of electrodes 201, 203, 205 and 207 may be consistent as shown in FIGS. 1 to 3. In some alternative embodiments as shown in FIGS. 4 and 5, the thicknesses of the plurality of electrodes 201, 203, 205 and 207 may be different. As shown in FIG. 4, the thickness of the first electrode 201a is less than that of the second electrode 203a; the thickness of the second electrode 203a is less than that of the third electrode 205a; and the thickness of the third electrode 205a is less than that of the fourth electrode 207a. Therefore, the thicknesses of the plurality of electrodes 201a, 203a, 205a and 207a are gradually increased from the first electrode 201a to the fourth electrode 207a. As shown in FIG. 5, the thickness of the first electrode 201b is greater than that of the second electrode 203b; the thickness of the second electrode 203b is greater than that of the third electrode 205b; and the thickness of the third electrode 205b is greater than that of the fourth electrode 207b. Therefore, the thicknesses of the plurality of electrodes 201b, 203b, 205b and 207b are gradually decreased from the first electrode 201b to the fourth electrode 207b.

The plurality of capacitor dielectric layers 202, 204, 206 and 208 include a first capacitor dielectric layer 202, a second capacitor dielectric layer 204, a third capacitor dielectric layer 206, and a fourth capacitor dielectric layer 208. The plurality of capacitor dielectric layers 202, 204, 206 and 208 may include a high dielectric constant (high k) material including HfO₂, Ta₂O₅, AlO, SiN, SiNO, Al₂O₃, TiO₂, ZrO₂, La₂O₃ or Pr₂O₃ and has a thickness equal to or less than about 500 angstroms (Å). In some embodiments, the thickness of each capacitor dielectric layers 202, 204, 206 and 208 may be equal to or less than about 300 Å. In some embodiments, the thickness of each capacitor dielectric layers 202, 204, 206 and 208 may be equal to or less than about 100 Å. The thicknesses of the plurality of capacitor dielectric layers 202, 204, 206 and 208 may be identical or different. As shown in FIGS. 1 to 5, the thicknesses of the plurality of capacitor dielectric layers 202, 204, 206 and 208 are substantially identical.

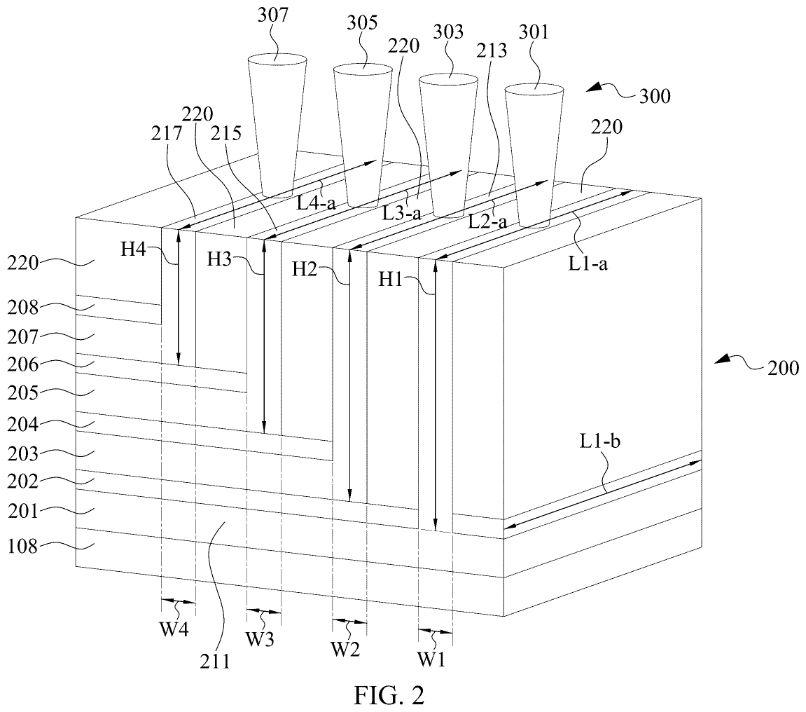

The plurality of connecting structures 211, 213, 215 and 217 are electrically coupled to the plurality of electrodes 201, 203, 205 and 207. The plurality of connecting structures 211, 213, 215 and 217 include a first connecting structure 211 connecting to the first electrode 201, a second connecting structure 213 connecting to the second electrode 203, a third connecting structure 215 connecting to the third electrode 205, and a fourth connecting structure 217 connecting to the fourth electrode 207. Tops of the connecting structures 211, 213, 215 and 217 are coplanar with each other and are substantially parallel to the front side 102 of the semiconductor substrate100. The plurality of connecting structures 211, 213, 215 and 217 comprise a second conductive material (e.g., titanium, titanium nitride, tantalum, tantalum nitride, tungsten, aluminum, copper and so on), which may be identical to the first conductive material of the plurality of electrodes 201, 203, 205 and 207. As shown in FIG. 2, length L1-a of the first connecting structure 211 may equal to length L1-b of the first electrode 201. Length L2 of the second connecting structure 213 may equal to length of the second electrode 203. Length L3 of the third connecting structure 215 may equal to length of the third electrode 205. Length L4 of the fourth connecting structure 217 may equal to length of the fourth electrode 207. Height H1 of the first connecting structure 211, height H2 of the second connecting structure 213, height H3 of the third connecting structure 215 and height H4 of the fourth connecting structure 217 are different from each other. Width W1 of the first connecting structure 211, width W2 of the second connecting structure 213, width W3 of the third connecting structure 215 and width W4 of the fourth connecting structure 217 may be identical or different from each other. Since the first electrode 201 is formed at a position near the substrate 100 while the fourth electrode 207 is formed at apposition away from the substrate 100, the height H1 of the first connecting structure 211 is greater than the height H2 of second connecting structure 213, the height H2 of the second connecting structure 213 is greater than the height H3 of third connecting structure 215, the height H3 of the third connecting structure 215 is greater than the height H4 of fourth connecting structure 217. The width W1 of the first connecting structure 211 is less than the width W2 of second connecting structure 213, the width W2 of the second connecting structure 213 is less than the width W3 of third connecting structure 215, the width W3 of the third connecting structure 215 is less than the width W4 of fourth connecting structure 217.

In some embodiments as shown in FIG. 1, the first connecting structure 211 is formed on the liner layer 108 of the semiconductor structure 100 and laterally connects to the first electrode 201. The second connecting structure 213 is formed on the second electrode 203 and thus longitudinally connects to the second electrode 203. The third connecting structure 215 is formed on the third electrode 205 and thus longitudinally connects to the third electrode 205. The fourth connecting structure 217 is formed on the third electrode 207 and thus longitudinally connects to the third electrode 207.

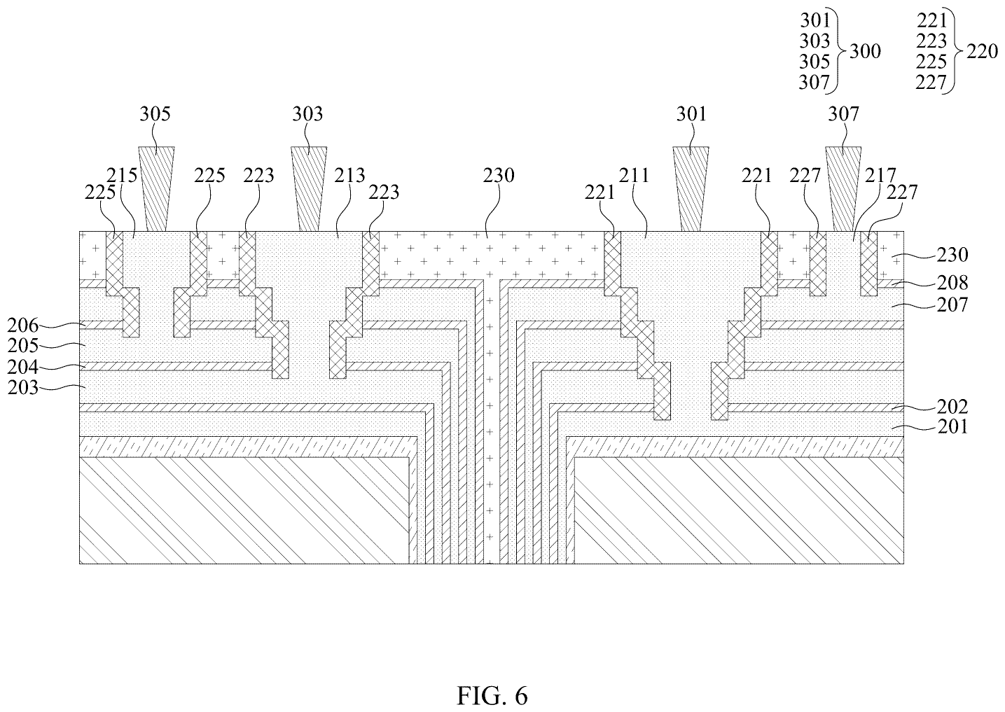

In some another embodiments as shown in FIGS. 2 to 5, the first connecting structure 211 is formed on the first electrode 201 and thus longitudinally connects to the first electrode 201. The second connecting structure 213 is formed on the first capacitor dielectric layer 202 and laterally connects to the second electrode 203. The third connecting structure 215 is formed on the second capacitor dielectric layer 204 and thus laterally connects to the third electrode 205. The fourth connecting structure 217 is formed on the third capacitor dielectric layer 206 and thus laterally connects to the third electrode 207. In some embodiments as shown in FIG. 6, the first connecting structure 211 longitudinally connects to the first electrode 201; the second connecting structure 213 longitudinally connects to the second electrode 203; the third connecting structure 215 longitudinally connects to the third electrode 205; and the fourth connecting structure 217 longitudinally connects to the third electrode 207.

The plurality of connecting structures 211, 213, 215 and 217 may have any shape. For example, as shown in FIGS. 1 to 5, each of the plurality of connecting structures 211, 213, 215 and 217 has a rectangular cross-section with a sidewall, which is substantially perpendicular to the front side 102 of the semiconductor substrate 100. In some alternative embodiments as shown in FIG. 6, some of the plurality of connecting structures 211a, 213a and 215a have a substantially inverted trapezoid cross-section with a staircase sidewall, which conforms to the contour of the adjacent layers while the others have a rectangular cross-section with a sidewall, which is substantially parallel to the front side 102 of the semiconductor substrate 100. For example, the sidewall of the first connecting structure 211 is longitudinally elongated from the first electrodes 201 and conformally deposited along an edge of the first capacitor dielectric layer 202, an edge of the second electrode 203, an edge of the second capacitor dielectric layer 204, an edge of the third electrode 205, an edge of the third capacitor dielectric layer 206, an edge of the fourth electrode 207 and an edge of the fourth capacitor dielectric layer 208. The sidewall of the second connecting structure 213 is longitudinally elongated from the second electrodes 203 and conformally deposited along an edge of the second capacitor dielectric layer 204, an edge of the third electrode 205, an edge of the third capacitor dielectric layer 206, an edge of the fourth electrode 207 and an edge of the fourth capacitor dielectric layer 208. The sidewall of the third connecting structure 215 is longitudinally elongated from the third electrodes 205 and conformally deposited along an edge of the third capacitor dielectric layer 206, an edge of the fourth electrode 207 and an edge of the fourth capacitor dielectric layer 208. The sidewall of the fourth connecting structure 217 is longitudinally elongated from the fourth electrodes 207 and conformally deposited along an edge of the fourth capacitor dielectric layer 208, so the sidewall of the fourth connecting structure 217 is substantially parallel to the front side 102 of the semiconductor substrate 100.

The plurality of separation structures 220 are formed over the liner layer 108 and surround the plurality of connecting structures 211, 213, 215 and 217 to separate the plurality of connecting structures 211, 213, 215 and 217 from each other and to ensure that the plurality of connecting structures 211, 213, 215 and 217 are merely coupled to the corresponding one of the plurality of electrodes 201, 203, 205 and 207. The separation structures 220 include an insulating material, such as silicon oxide, silicon nitride, silicon oxynitride, silicon carbide, or other suitable materials.

When each of the plurality of connecting structures 211, 213, 215 and 217 has a rectangular cross-section as shown in FIG. 1, each of the separation structures 220 surrounds the plurality of connecting structures 211, 213, 215 and 217 and may partially conformally deposited along the adjacent electrodes 201, 203, 205 and 207 and adjacent capacitor dielectric layers 202, 204, 206 and 208. When each of the plurality of connecting structures 211, 213, 215 and 217 has a rectangular cross-section as shown in FIGS. 2 to 5, the separation structures 220 are formed on capacitor dielectric layers 202, 204, 206 and 208 and between two of the plurality of connecting structures 211, 213, 215 and 217. In some embodiments, top surfaces of the separation structures 220 are coplanar or level with top surfaces of the connecting structures 211, 213, 215, 217. In such embodiments, a flush surface may be obtained, as shown in FIGS. 1 to 5.

When each of the plurality of connecting structures 211, 213, 215 and 217 has an inverted trapezoid cross-section and a staircase sidewall as shown in FIG. 6, each of the separation structures 220 is a thin film with a consistent thickness, which is conformally formed along some of the plurality of electrode 201, 203, 205 and 207 and some of the plurality of capacitor dielectric layers 202, 204, 206 and 208. Therefore, the connecting structures 211, 213, 215 and 217 serve as spacers separating the plurality of electrode 201, 203, 205 and 207 from adjacent layers. A bottom of the fourth separation structure 227 longitudinally protrudes into the fourth electrode 217 to mitigate interference from the adjacent layers. In some embodiments, the bottom of each of the separation structures 221, 223, 225 and 227 longitudinally protrudes into the corresponding one of the connecting structures 211, 213, 215 and 217 at a depth equal to or less than about three quarters of the thickness of the corresponding one of the connecting structures 211, 213, 215 and 217. In some embodiments, the bottom of each of the separation structures 221, 223, 225 and 227 longitudinally protrudes into the corresponding one of the connecting structures 211, 213, 215 and 217 at a depth equal to or less than about a half of the thickness of the corresponding one of the connecting structures 211, 213, 215 and 217. In some embodiments, the bottom of each of the separation structures 221, 223, 225 and 227 longitudinally protrudes into the corresponding on-e of the connecting structures 211, 213, 215 and 217 at a depth equal to or less than about one quarter of the thickness of the corresponding one of the connecting structures 211, 213, 215 and 217.

For example, the plurality of separation structures 220 include a first separation structure 221, a second separation structure 223, a third separation structure 225 and a fourth separation structure 227. The first separation structure 221 surrounds the first connecting structure 211 and is deposited between the first connecting structure 211 and the adjacent layers including the first capacitor dielectric layer 202, the second electrode 203, the second capacitor dielectric layer 204, the third electrode 205, the third capacitor dielectric layer 206, the fourth electrode 207, the fourth capacitor dielectric layer 208 and an ILD layer 230. A bottom of the first separation structure 221 longitudinally protrudes into the first electrode 211 to mitigate interference from the adjacent layers.

The second separation structure 223 surrounds the second connecting structure 213 and is deposited between the second connecting structure 213 and the adjacent layers including the second capacitor dielectric layer 204, the third electrode 205, the third capacitor dielectric layer 206, the fourth electrode 207, the fourth capacitor dielectric layer 208 and the ILD layer 230. A bottom of the second separation structure 223 longitudinally protrudes into the second electrode 213 to mitigate interference from the adjacent layers.

The third separation structure 225 surrounds the third connecting structure 215 and is deposited between the third connecting structure 215 and the adjacent layers including the third capacitor dielectric layer 206, the fourth electrode 207, the fourth capacitor dielectric layer 208 and the ILD layer 230. A bottom of the third separation structure 225 longitudinally protrudes into the third electrode 215 to mitigate interference from the adjacent layers.

The fourth separation structure 227 surrounds the fourth connecting structure 217 and is deposited between the fourth connecting structure 217 and the adjacent layers including the fourth capacitor dielectric layer 208 and the ILD layer 230. A bottom of the fourth separation structure 227 longitudinally protrudes into the fourth electrode 217 to mitigate interference from the adjacent layers.

Materials for forming the separation structures 220 may be identical or similar to those for forming the ILD layer 230. In some embodiments, the separation structure 220 may be referred to as an ILD. Tops of the first separation structure 221, the second separation structure 223, the third separation structure 225 and the fourth separation structure 227 are coplanar with the tops of the connecting structures 211, 213, 215 and 217 and are substantially perpendicular to the front side 102 of the semiconductor substrate 100. In some embodiments, the top surfaces of the separation structures 221, 223, 225, 227, and the top surfaces of the connecting structures 211, 213, 215, 217 are coplanar or level with the top surface of the ILD layer 230. In such embodiments, a flush surface may be obtained, as shown in FIG. 6.

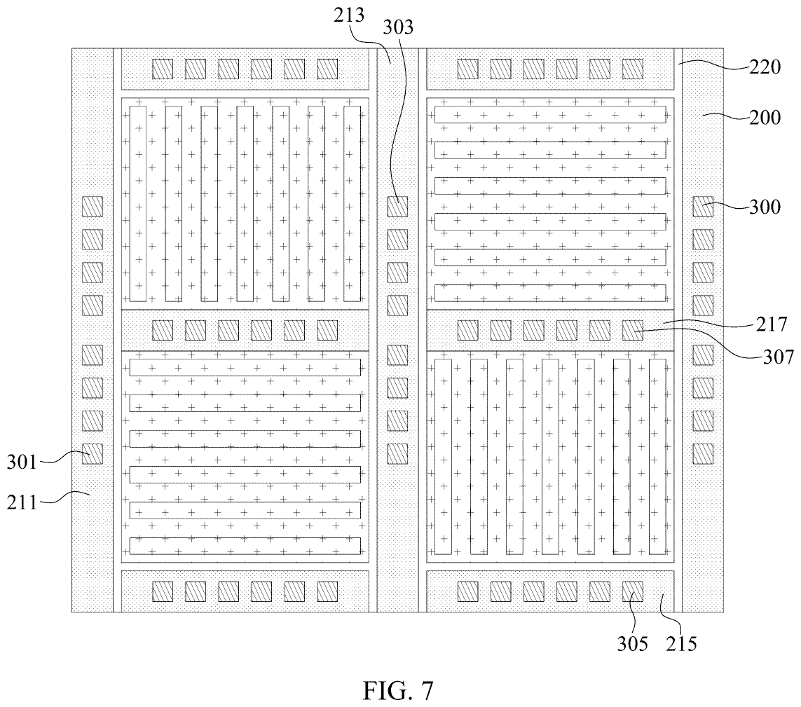

Each of the plurality of conductive vias 300 is electrically coupled to corresponding electrodes 201, 203, 205 and 207 through the plurality of connecting structures 211, 213, 215 and 217. Since the tops of all the connecting structures 211, 213, 215 and 217 are at the same level and the plurality of conductive vias 300 can easily land on the corresponding one of the connecting structures 211, 213, 215 and 217 at the same level as shown in FIGS. 1 to 6, procedures for forming the semiconductor structure of the present disclosure can be easily controlled and the process window would be wider as shown in FIG. 7, which illustrates a top view of the semiconductor structure of the present disclosure. Referring to FIG. 7, two or more vias 300 are formed on one connecting structure 211, 213, 215 and 217. For example, there are eight vias 300 formed on the second connecting structure 213. In some embodiments, two or more vias 300 are formed on each of the connecting structures 211, 213, 215 and 217.

Each of the plurality of conductive vias 300 has a bottom connecting to a top of a corresponding connecting structures 211, 213, 215 and 217, and a top opposite to the bottom. The bottoms of the plurality of conductive vias 300 are coplanar. An area of the bottom of each of the plurality of conductive vias 300 is smaller than that of the top of the corresponding connecting structure 211, 213, 215 and 217. An area of the top of each of the plurality of conductive vias 300 is smaller than that of the top of the corresponding connecting structure 211, 213, 215 and 217.

Each conductive via 300 may have any shape and may be a cylinder, triangular prism, quadrilateral prism, polygonal prism and the like, which are merely examples and are not intended to be limiting. In some embodiments, the area of the top of each of the plurality of conductive vias 300 is greater than the area of the bottom of each of the plurality of conductive vias 300.

The conductive vias 300 comprise a third conductive material (e.g., titanium, titanium nitride, tantalum, tantalum nitride, tungsten, aluminum, copper and so on). In some 1 embodiments, the third conductive material may be identical to the second conductive material of the connecting structures 211, 213, 215 and 217. In some alternative embodiments, the third conductive material may be different from the second conductive material of the connecting structures 211, 213, 215 and 217. In some embodiments, the third conductive material may be identical to the first conductive material of the plurality of electrodes 201, 203, 205 and 207. In some alternative embodiments, the third conductive material may be different from the first conductive material of the plurality of electrodes 201, 203, 205 and 207.

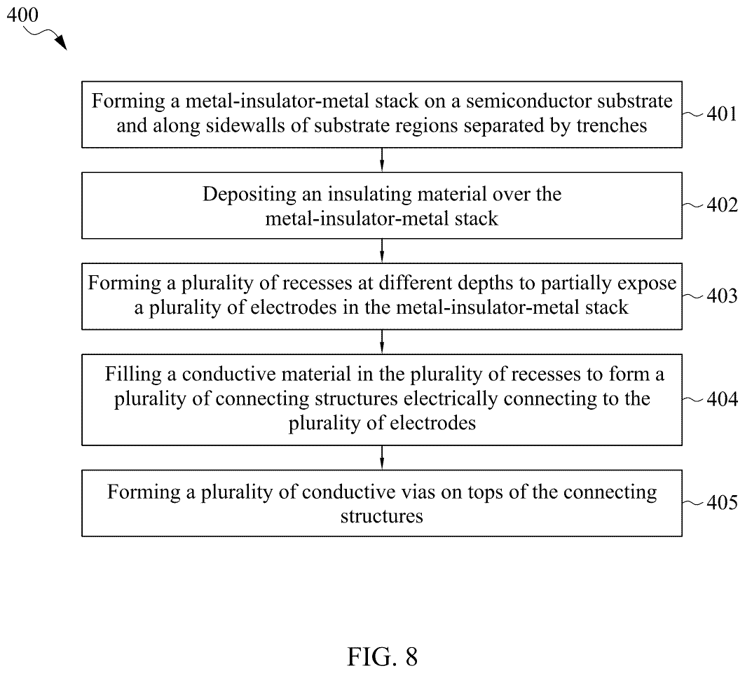

FIG. 8 is a flowchart representing a method 400 of manufacturing a semiconductor structure according to various aspects of the present disclosure in accordance with some embodiments. In some embodiments, the method 400 of manufacturing the semiconductor structure includes a number of operations (401, 402, 403, 404 and 405). The method 400 of manufacturing the semiconductor structure will be further described according to one or more embodiments. It should be noted that the operations of the method 400 may be rearranged or otherwise modified within the scope of the various aspects. It should further be noted that additional processes may be provided before, during, and after the method 400, and that some other processes may be only briefly described herein.

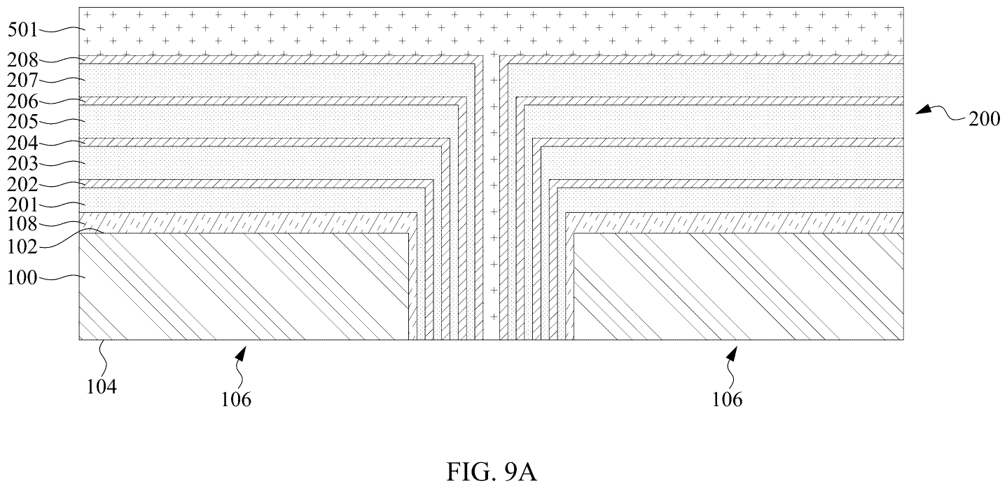

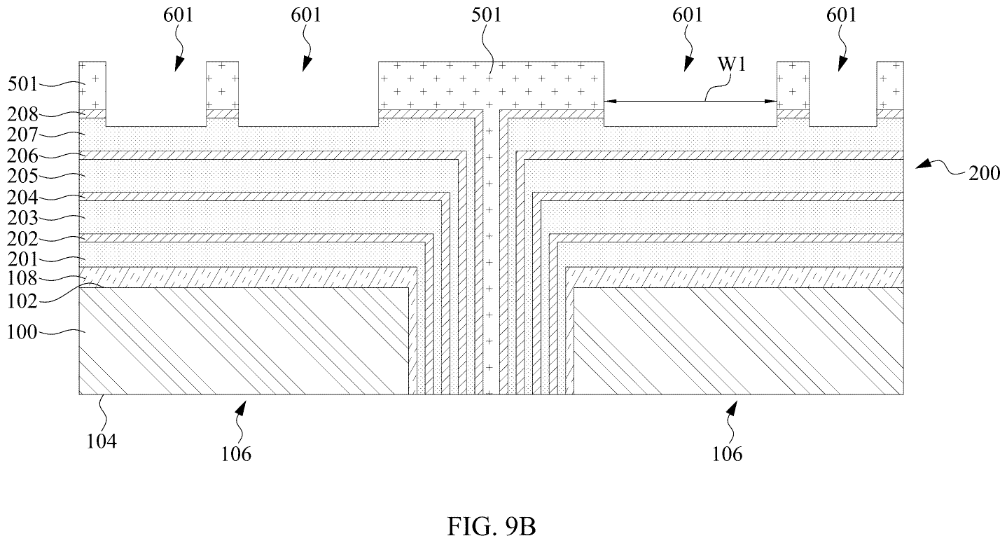

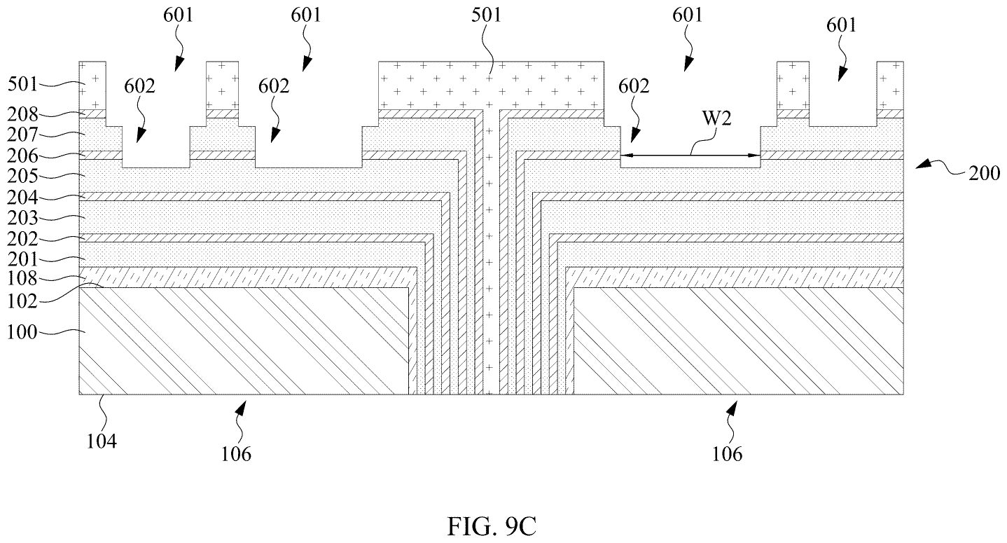

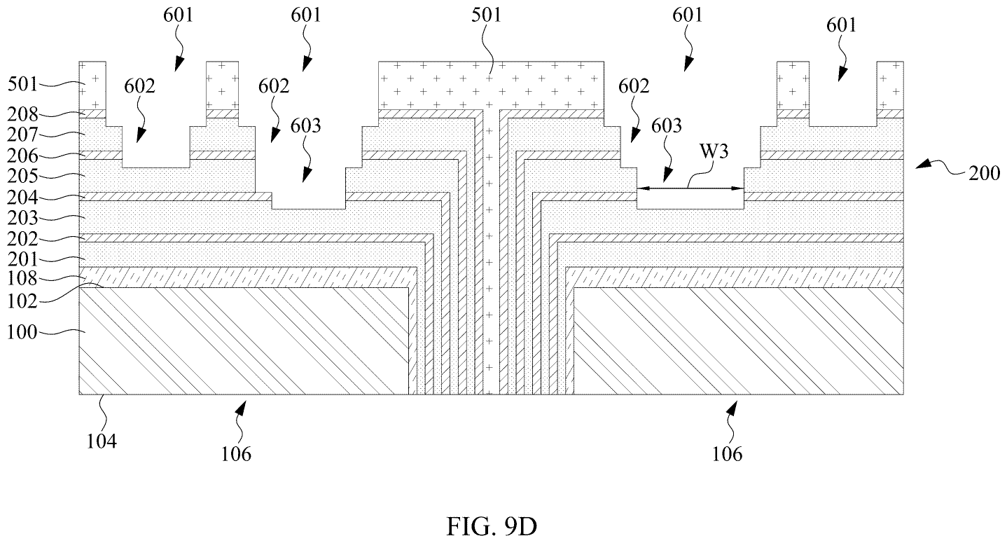

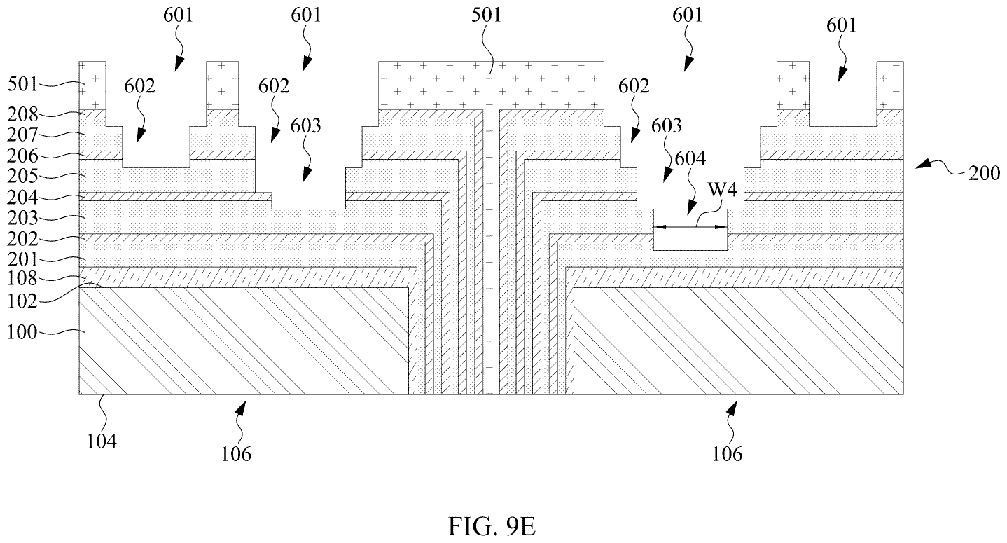

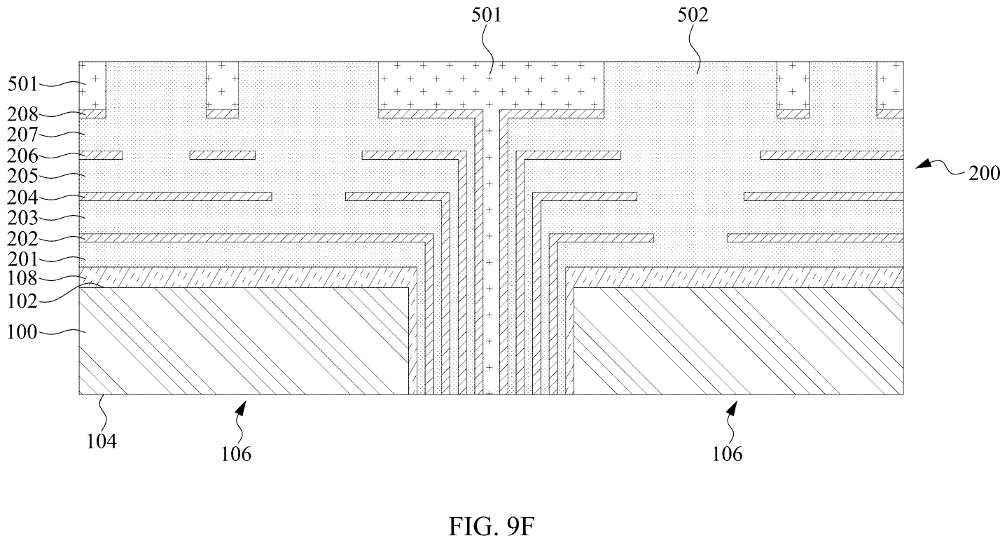

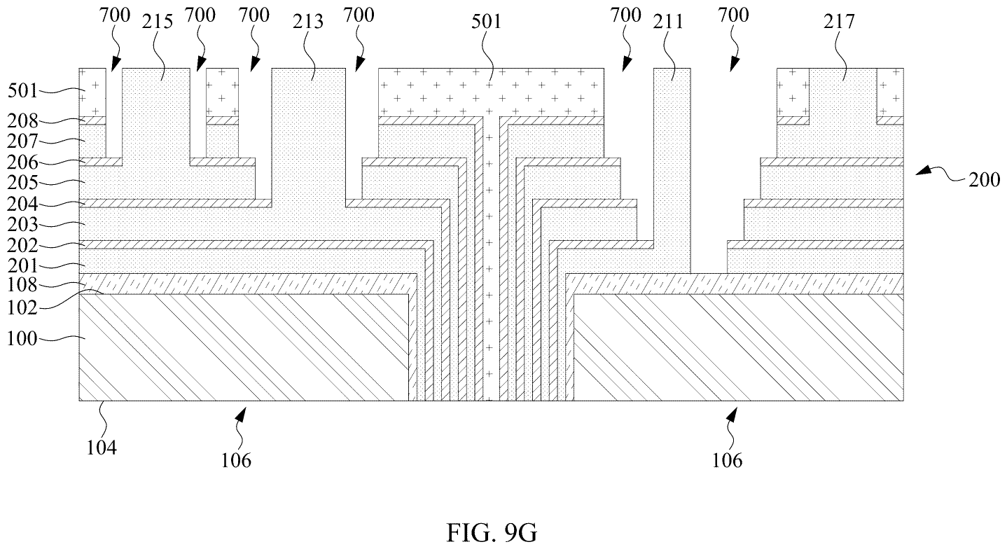

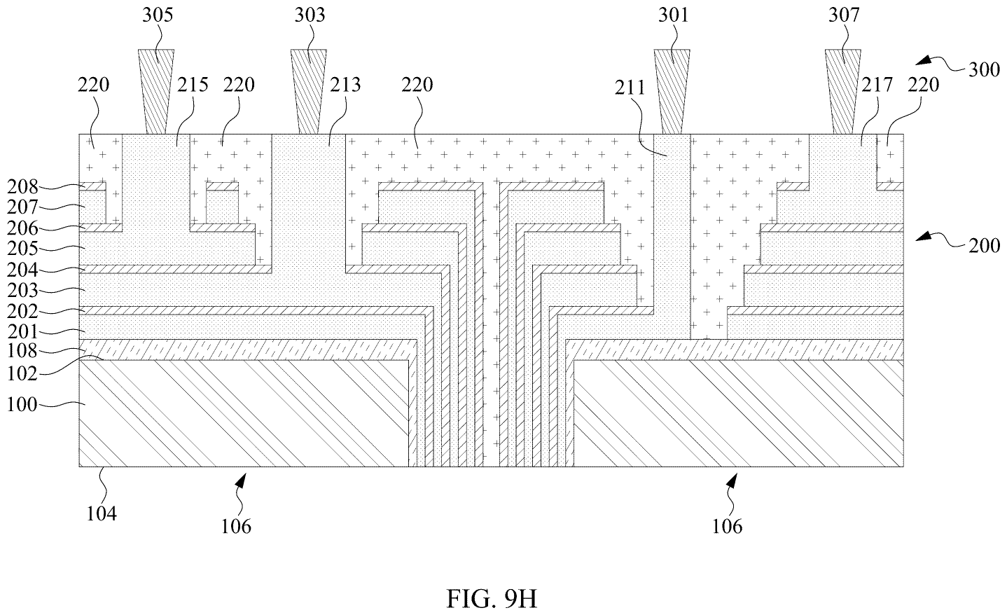

As shown in FIG. 9A, method 400 begins at operation 401 by forming a metal-insulator-metal (MIM) stack on a semiconductor substrate and along sidewalls of substrate regions separated by trenches. In this operation, at least one trench is formed in a semiconductor substrate 100. The trench with a predetermined aspect ratio is formed from a front side 102 toward a second side 104 in the semiconductor substrate 100 to define substrate regions 106 besides the trench. The semiconductor substrate 100 with the trench is overlaid with a liner layer 108. The MIM may stack on the semiconductor substrate 100 with the liner layer 108 and along sidewalls of the substrate regions106. Forming the MIM stack comprises sequentially depositing a first electrode 201, a first capacitor dielectric layer 202, a second electrode 203, a second capacitor dielectric layer 204, a third electrode 205, a third capacitor dielectric layer 206, a fourth electrode 207 and a fourth capacitor dielectric layer 208 over the semiconductor substrate 100 with the trench.

At next operation 402, a first insulating material 501 is deposited over the MIM stack and thus formed on the fourth capacitor dielectric layer 208 over the semiconductor substrate 100 and also fills a space surrounded by the fourth capacitor dielectric layer 208.

At operation 403, a plurality of recesses 601, 602, 603 and 604 are formed at different depths through one mask or several masks to partially expose a plurality of electrodes 201, 203, 205 and 207 of the MIM stack. The number of deeper recesses formed at a deeper position in the semiconductor substrate 100 is less than the number of shallower recesses formed at a shallower position in the semiconductor substrate 100 and a width of a deeper recess is smaller than a width of a shallower recess.

In some embodiments, the plurality of recesses 601, 602, 603 and 604 may be formed through several masks. As shown in FIG. 9B, a plurality of first recesses 601 are formed by partially etching the first insulating material 501, the fourth capacitor dielectric layer 208 and etching an upper portion of the fourth electrode 207 to expose the fourth electrode 207. As shown in FIG. 9C, a plurality of second recesses 602 are formed by partially etching the fourth electrode 207 exposed from the first recesses 601, the third capacitor dielectric layer 206 and etching an upper portion of the third electrode 205 to expose the third electrode 205. As shown in FIG. 9D, a plurality of third recesses 603 are formed by partially etching the third electrode 205 exposed from the second recesses 602, the second capacitor dielectric layer 204 and etching an upper portion of the second electrode 203 to expose the second electrode 203. As shown in FIG. 9E, a plurality of fourth recesses 604 are formed by partially etching the second electrode 203 exposed from the third recesses 603, the first capacitor dielectric layer 202 and etching an upper portion of the first electrode 201 to expose the first electrode 201. In some alternative embodiments, as mentioned above, the plurality of recesses 601, 602, 603 and 604 may be formed through only one mask.

The number of the first recesses 601 is greater than the number of the second recesses 602. The number of the second recesses 602 is greater than the number of the third recesses 603. The number of the third recesses 603 is greater than the number of the fourth recesses 604. Each first recess 601 has a first width W1, which is greater than a second width W2 of the second recess 602 communicating to the first recess 601. The second width W2 of the second recess 602 is greater than a third width W3 of the third recess 603 communicating to the second recess 602. The third width W3 of the third recess 603 is greater than a fourth width W4 of the fourth recess 604 communicating to the third recess 603. Therefore, due to different widths of the first recess 601, the second recess 602, the third recess 603 and the fourth recess 604, openings formed by any two of the first recess 601, the second recess 602, the third recess 603 and the fourth recess 604 have staircase sidewalls.

At operation 404, a plurality of connecting structures 211, 213, 215 and 217 are formed to electrically connect the electrodes 201, 203, 205 and 207 by filling a conductive material 502 in the recesses 601, 602, 603 and 604 and performing planarization, such as a chemical mechanical planarization (CMP), as shown in FIG. 9F so that tops of the plurality of connecting structures is coplanar with each other; and performing several etching processes to form the plurality of connecting structures 211, 213, 215 and 217 with different heights as shown in FIG. 9G.

Referring to FIG. 9G, in some embodiments, formation of the plurality of connecting structures 211, 213, 215 and 217 includes applying at least one hard mask and partially etching the conductive material 502 and partially etching the electrodes 201, 203, 205 and 207 uncovered by the capacitor dielectric layers 202, 204, 206 and 208 to form openings 700 and a first connecting structure 211 on the liner layer 108 of the semiconductor substrate 100, which laterally connects to the first electrode 201, to form a second connecting structure 213 on the second electrode 203, which longitudinally connects to the second electrode 203, to form a third connecting structure 215 on the third electrode 205, which longitudinally connects to the third electrode 205. The remaining conductive material 502 formed in the fourth electrode 207 serves as a fourth connecting structure 217. Therefore, a sidewall of each of the plurality of connecting structures 211, 213, 215 and 217 is perpendicular to the front side 102 of the semiconductor substrate 100. In some embodiments, the sidewalls of the connecting structures 211, 213, 215 and 217 are exposed through the openings 700. The conductive material 502 may be identical to materials for forming the electrodes 201, 203, 205 and 207. The conductive material 502 and the materials for forming the electrodes 201, 203, 205 and 207 have an etch rate higher than an etch rate of the material for forming the capacitor dielectric layers 202, 204, 206 and 208, so the plurality of electrodes 201, 203, 205 and 207 and the conductive material 502 uncovered by the hard masks or the capacitor dielectric layers 202, 204, 206 and 208 can be removed. For example, the etch rate of the higher than an etch rate of the material for forming the capacitor dielectric layers 202, 204, 206 and 208. In addition, tops of the plurality of connecting structures 211, 213, 215 and 217 are aligned with the top of the remaining first insulating material 501. In some embodiments, a second insulating material can be filled in the openings 700 to surround the plurality of connecting structures 211, 213, 215 and 217 after the plurality of connecting structures 211, 213, 215 and 217 are formed. The second insulating material and the remaining first insulating material 501 may become a portion of an inter-layer dielectric (ILD) layer formed in the following procedure. The ILD layer may ensure that the plurality of connecting structures 211, 213, 215 and 217 connect to a corresponding electrode 201, 203, 205 and 207 and are separated from adjacent layers.

At operation 405 as shown in FIG. 9H, a plurality of conductive vias 300 are formed on the tops of the plurality of connecting structures 211, 213, 215 and 217, which include a first conductive via 301 landing on a top of the first connecting structure 211 so as to electrically coupled to the first electrode 201, a second conductive via 303 landing on a top of the second connecting structure 213 so as to electrically coupled to the second electrode 203, a third conductive via 305 landing on a top of the third connecting structure 213 so as to electrically coupled to the third electrode 205, and a fourth conductive via 307 landing on a top of the fourth connecting structure 217 so as to electrically coupled to the fourth electrode 207. Since the tops of the plurality of connecting structures 211, 213, 215 and 217 are coplanar, bottoms of the plurality of conductive vias 300 maybe at the same level.

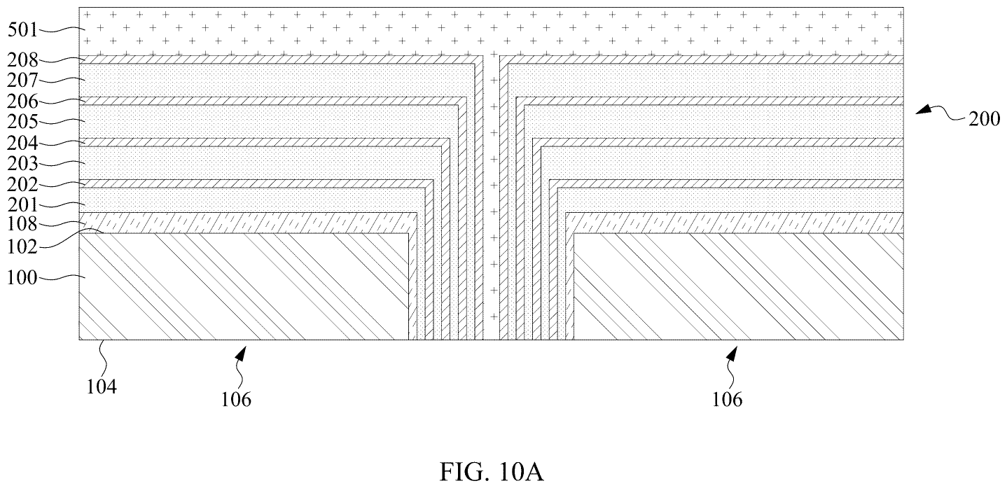

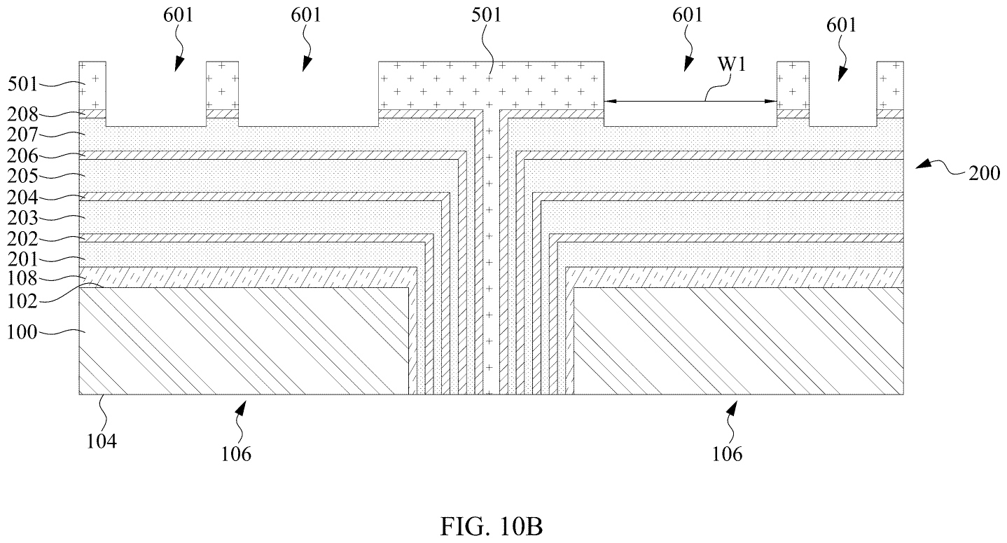

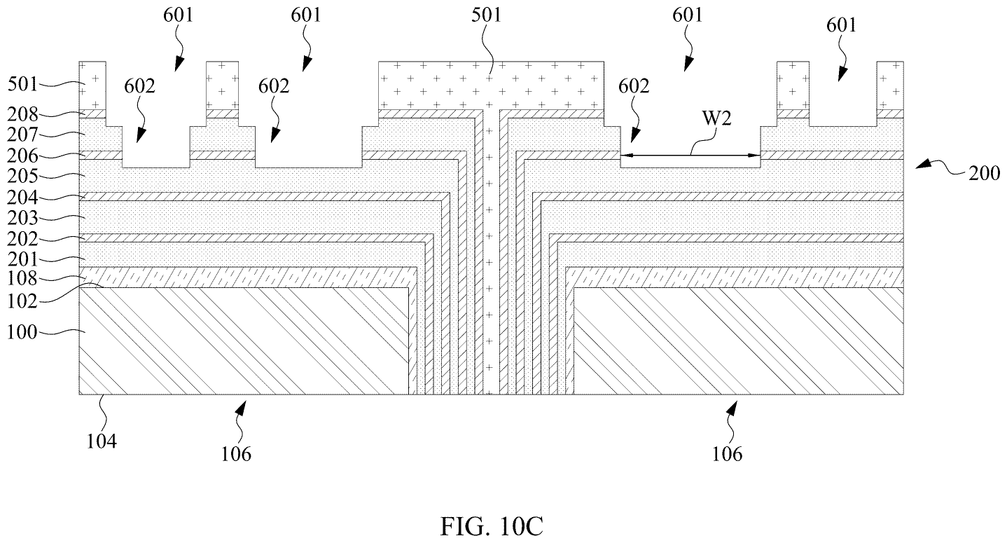

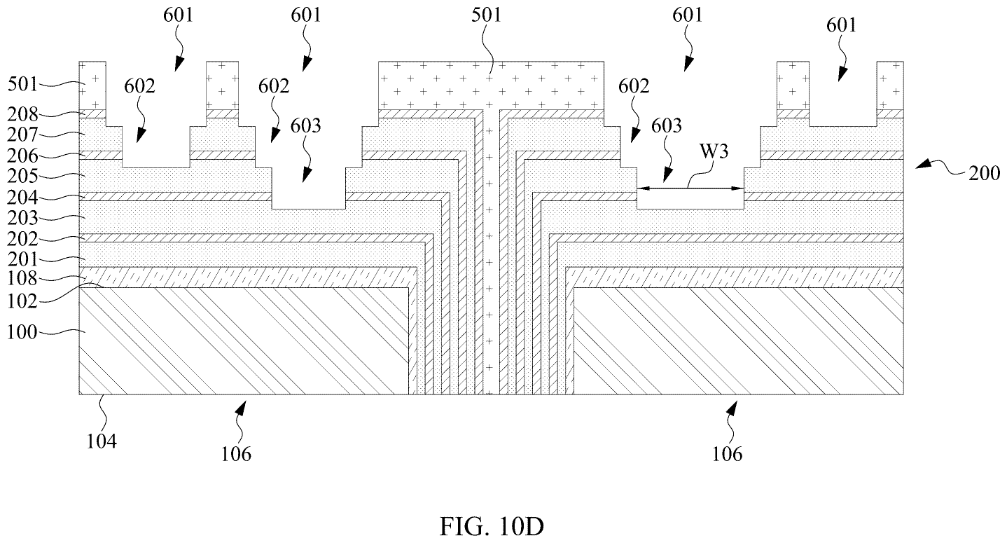

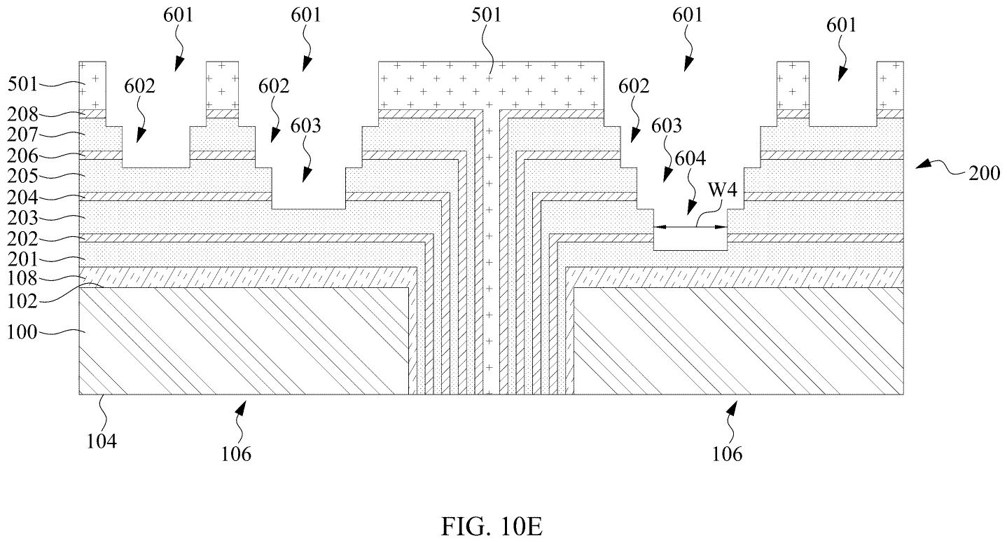

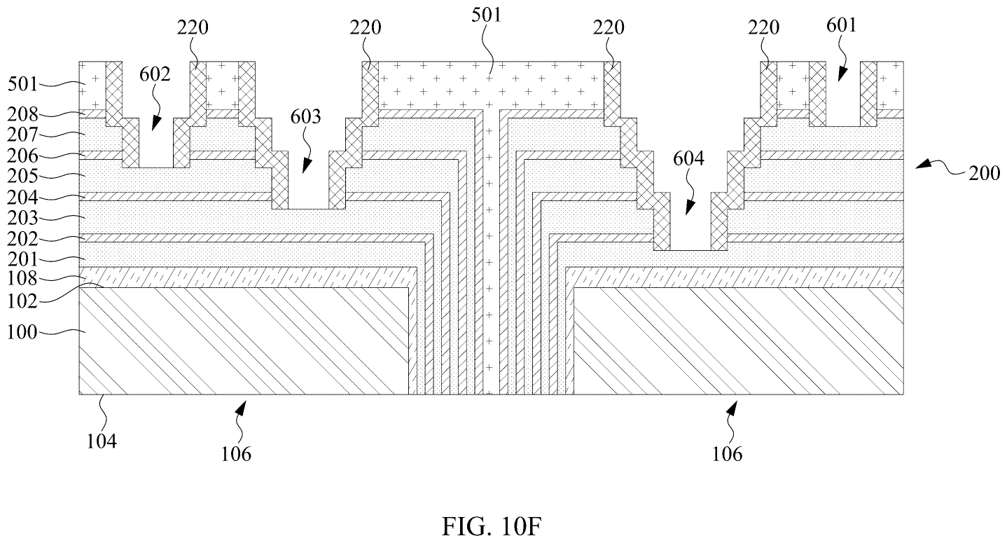

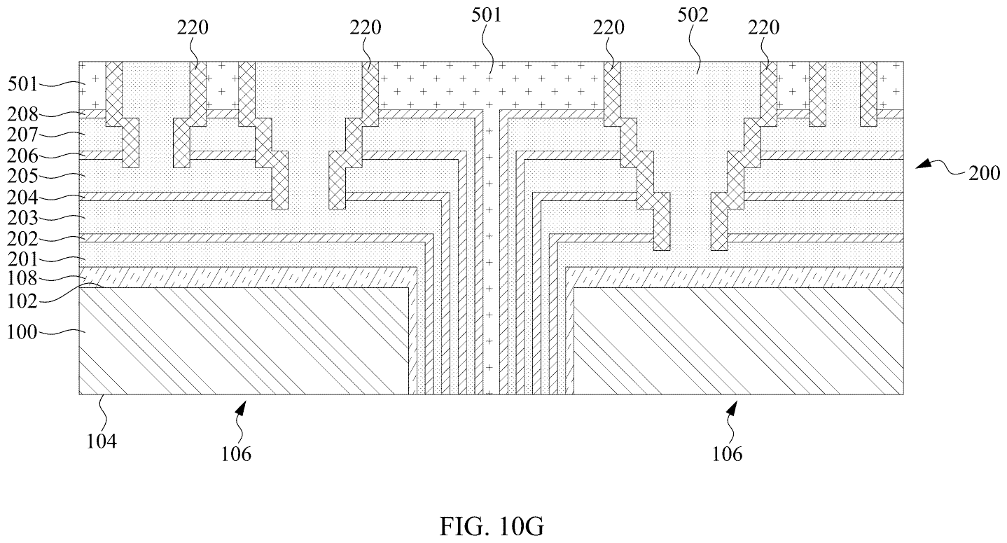

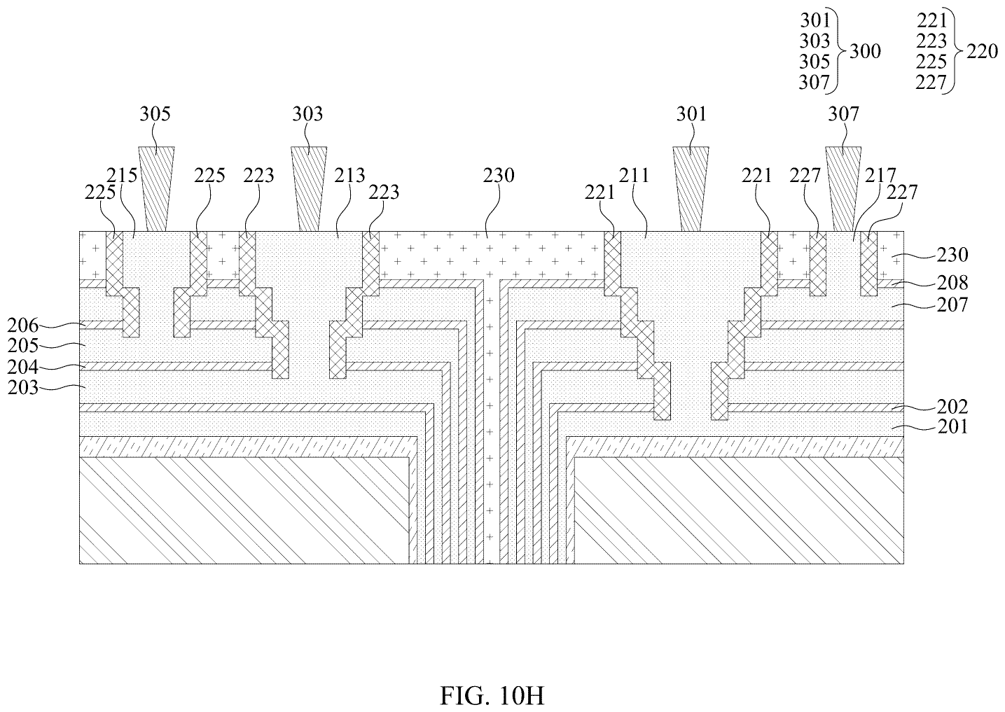

FIGS. 10A to 10H illustrate an alternative method of manufacturing a semiconductor structure according to various aspects of the present disclosure. Operations 401 to 403 shown in FIGS. 10A to 10E are substantially identical to those illustrated in FIGS. 9A to 9E.

At operation 404, as shown in FIG. 10F, a second insulating material is conformally deposited to cover sidewalls and bottoms of the recesses 601, 602, 603 and 604 and to cover the remaining first insulating material 501, which serves as a portion of an inter-layer dielectric (ILD) layer 230 formed in the following procedure as shown in FIG. 10H. An etching back may be performed to remove portions of the second insulating material from the bottoms of the recesses 601, 602, 603 and 604 and from the remaining first insulating material 501 thereby exposing a portion of the tops the electrodes 201, 203, 205 and 207. Further, a plurality of separation structures 220 (including a first separation structure 221, a second separation structure 223, a third separation structure 225 and a fourth separation structure 227) are formed along the sidewalls of the recesses 601, 602, 603 and 604.

Referring to FIG. JOG, a conductive material 502 is filled within the recesses 601, 602, 603 and 604 on the exposed tops of the electrodes 201, 203, 205 and 207, and a planarization, such as CMP, is performed to remove superfluous conductive material. Accordingly, a plurality of connecting structures 211, 213, 215 and 217 surrounded by the separation structures 220 are obtained. Each of the first, second and third connecting structures 211, 213 and 215 also has a staircase sidewall corresponding to the sidewall of the opening formed by any two of the first recess 601, the second recess 602, the third recess 603 and the fourth recess 604 have staircase sidewalls. The fourth connecting structure 217 formed on the fourth electrode 207 has a sidewall perpendicular to the front side 102 of the semiconductor substrate 100.

Referring to FIGS. 10G and 10H, the tops of the first separation structure 221, the second separation structure 223, the third separation structure 225 and the fourth separation structure 227 are coplanar with the tops of the connecting structures 211, 213, 215 and 217. In some embodiments, the tops of the separation structures 221, 223, 225 and 227, the tops of the connecting structures 211, 213, 215 and 217, and the tops of the first insulating material 501, which serves as a portion of the ILD layer 230 as illustrated in FIG. 10H are coplanar or level with each other.

At operation 405 as shown in FIG. 10H, a plurality of conductive vias 300 are formed on the tops of the plurality of connecting structures 211, 213, 215 and 217, which include a first conductive via 301 landing on a top of the first connecting structure 211 so as to electrically coupled to the first electrode 201, a second conductive via 303 landing on a top of the second connecting structure 213 so as to electrically coupled to the second electrode 203, a third conductive via 305 landing on a top of the third connecting structure 213 so as to electrically coupled to the third electrode 205, and a fourth conductive via 307 landing on a top of the fourth connecting structure 217 so as to electrically coupled to the fourth electrode 207. Since the tops of the plurality of connecting structures 211, 213, 215 and 217 are coplanar, the plurality of conductive vias 300 may have the same height.

The tops of the plurality of connecting structures 211, 213, 215 and 217 are at the same level, which enlarges the process window, so the plurality of conductive vias 300 can easily land on the plurality of connecting structures 211, 213, 215 and 217 and can be accurately coupled to the plurality of electrodes 201, 203, 205 and 207 to improve reliability the semiconductor structure. The resulting DTC can have reduced contact resistance and leakage.

In some embodiments, a semiconductor structure comprises a semiconductor substrate having a plurality of substrate regions formed in a front side of the semiconductor substrate; at least one capacitor structure separating the plurality of substrate regions, wherein the at least one capacitor structure is formed over the front side of the semiconductor substrate and is along sidewalls of the substrate regions and comprises: a plurality of electrodes and a plurality of capacitor dielectric layers alternately disposed on the front side of the semiconductor substrate; a plurality of connecting structures each electrically coupled to one of the plurality of electrodes at a position above the front side of the substrate, wherein tops of the plurality of connecting structures are coplanar with each other and substantially perpendicular to the front side of the semiconductor substrate; and a plurality of separation structures separating respective connecting structure from other ones of the plurality of electrodes; and a plurality of conductive vias each has a bottom connecting to a top of a corresponding connecting structures, wherein an area of the bottom of each of the plurality of conductive vias is smaller than that of the top of the corresponding connecting structure.

In some embodiments, a deep trench capacitor comprises a first electrode; a second electrode parallel to the first electrode; a first connecting structure coupled to the first electrode; and a second connecting structure coupled to the second electrode, wherein a height of the first connecting structure is different from a height of the second connecting structure, and a width of the first connecting structure is different from a width of the second connecting structure, wherein a length of the first connecting structure equals to a length of the first electrode; and a length of the second connecting structure equals to a length of the second electrode.

In some embodiments, a method of manufacturing a semiconductor structure comprises forming a metal-insulator-metal stack over a front side of a semiconductor substrate and along sidewalls of substrate regions, wherein the metal-insulator-metal stack comprises a plurality of electrodes and a plurality of capacitor dielectric layers alternately disposed on the front side of the semiconductor substrate; depositing a first insulating material over the metal-insulator-metal stack; forming a plurality of recesses at different depths to expose each of the plurality of electrodes in the metal-insulator-metal stack from the plurality of recesses; forming a plurality of connecting structures in the plurality of recesses so that each of the plurality of connecting structures electrically connects to one of the plurality of electrodes; performing a planarization so that tops of the connecting structures are coplanar with each other and substantially parallel to the front side of the semiconductor substrate; and forming a plurality of conductive vias on the tops of the connecting structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a semiconductor substrate having a plurality of substrate regions formed in a front side of the semiconductor substrate;
at least one capacitor structure separating the plurality of substrate regions, wherein the at least one capacitor structure is formed over the front side of the semiconductor substrate and is along sidewalls of the substrate regions and comprises:
a plurality of electrodes and a plurality of capacitor dielectric layers alternately disposed on the front side of the semiconductor substrate;
a plurality of connecting structures each electrically coupled to one of the plurality of electrodes at a position above the front side of the semiconductor substrate, wherein tops of the plurality of connecting structures are coplanar with each other and substantially perpendicular to the front side of the semiconductor substrate; and
a plurality of separation structures separating respective connecting structure from other ones of the plurality of electrodes; and
a plurality of conductive vias each has a bottom connecting to a top of a corresponding connecting structures, wherein an area of the bottom of each of the plurality of conductive vias is smaller than that of the top of the corresponding connecting structure.

2. The semiconductor structure of claim 1, wherein at least one of the plurality of connecting structures has a rectangular cross-section with a sidewall substantially perpendicular to the front side of the semiconductor substrate.

3. The semiconductor structure of claim 1,
wherein at least one of the plurality of connecting structures has an inverted trapezoid cross-section with a staircase sidewall conformally along adjacent ones of the plurality of electrodes and adjacent ones of the plurality of capacitor dielectric layers; and
wherein each of the plurality of connecting structures is formed on one of the plurality of electrodes.

4. The semiconductor structure of claim 3, wherein each of the separation structures comprises a thin film with a consistent thickness, which is conformally formed along adjacent ones of the plurality of electrode and adjacent ones of the plurality of capacitor dielectric layers.

5. The semiconductor structure of claim 4, wherein a bottom of each of the separation structures longitudinally protrudes into one of the plurality electrodes.

6. The semiconductor structure of claim 1, wherein the semiconductor substrate comprises a liner layer formed on the front side of the semiconductor substrate and along the sidewalls of the substrate regions, so that the at least one capacitor structure is formed on the liner layer.

7. The semiconductor structure of claim 1, wherein a height of the first connecting structure is greater than a height of the second connecting structure, and a width of the first connecting structure is less than a width of the second connecting structure; the height of the second connecting structure is greater than a height of the third connecting structure, and the width of the second connecting structure is less than a width of the third connecting structure; and the height of the third connecting structure is greater than a height of the fourth connecting structure, and the width of the third connecting structure is less than a width of the fourth connecting structure.

8. The semiconductor structure of claim 1, wherein the plurality of connecting structures comprise a first material and the plurality of conductive vias comprise a second material, wherein the first material is different from the second material.

9. A deep trench capacitor, comprising
a first electrode;
a second electrode parallel to the first electrode;
a first connecting structure coupled to the first electrode; and
a second connecting structure coupled to the second electrode,
wherein a height of the first connecting structure is different from a height of the second connecting structure, and a width of the first connecting structure is different from a width of the second connecting structure,
wherein a length of the first connecting structure equals to a length of the first electrode; and a length of the second connecting structure equals to a length of the second electrode.

10. The deep trench capacitor of claim 9, wherein the first connecting structure, the second connecting structure, the first electrode and the second electrode comprise a same material.

11. The deep trench capacitor of claim 9, wherein a top of the first connecting structure is coplanar with a top of the second connecting structure.

12. The deep trench capacitor of claim 9, wherein the height of the first connecting structure is greater than the height of the second connecting structure and the width of the first connecting structure is less than the width of the second connecting structure.

13. The deep trench capacitor of claim 9, wherein one of the first connecting structure and the second connecting structure laterally connects a corresponding electrode and the other one of the first connecting structure and the second connecting structure longitudinally connects the second electrode.

14. The deep trench capacitor of claim 9, wherein both of the first connecting structure and the second connecting structure longitudinally connect the first electrode and the second electrode, respectively.

15. A method of manufacturing a semiconductor structure, comprising:
forming a metal-insulator-metal stack over a front side of a semiconductor substrate and along sidewalls of substrate regions, wherein the metal-insulator-metal stack comprises a plurality of electrodes and a plurality of capacitor dielectric layers alternately disposed on the front side of the semiconductor substrate;
depositing a first insulating material over the metal-insulator-metal stack;
forming a plurality of recesses at different depths to expose each of the plurality of electrodes in the metal-insulator-metal stack from the plurality of recesses;
forming a plurality of connecting structures in the plurality of recesses so that each of the plurality of connecting structures electrically connects to one of the plurality of electrodes;
performing a planarization so that tops of the connecting structures are coplanar with each other and substantially parallel to the front side of the semiconductor substrate; and
forming a plurality of conductive vias on the tops of the connecting structures.

16. The method of claim 15, wherein forming the plurality of connecting structures comprises:
filling a conductive material in the plurality of recesses; and partially removing the conductive material,
wherein each of the plurality of connecting structures has a rectangular cross-section with a sidewall, which is substantially perpendicular to the front side of the semiconductor substrate.

17. The method of claim 15, further comprising forming a plurality of separation structures by filling the recesses with a second insulating material to surround the plurality of connecting structures after the plurality of connecting structures are formed.

18. The method of claim 15, further comprising forming a plurality of separation structures by conformally depositing a second insulating material along sidewalls of the recesses before forming the plurality of connecting structures.

19. The method of claim 15, wherein at least one of the plurality of connecting structures laterally connects to a corresponding one of the plurality of electrodes and at least one of the plurality of connecting structures longitudinally connects a corresponding one of the plurality of electrodes.

20. The method of claim 15, wherein each of the plurality of connecting structures longitudinally connects to a corresponding one of the plurality of electrodes.
